(19) United States
(12) Patent Application Publication
(10) Pub. No.: US 2009/0085128 A1
(43) Pub. Date: Apr. 2, 2009

(54) SEMICONDUCTOR DEVICE AND METHOD FOR MANUFACTURING SAME

(75) Inventors: Yuki Nakamura, Kanagawa-ken (JP); Masaaki Yamamoto, Oita-ken (JP); Katsu Honna, Kanagawa-ken (JP); Hisanori Furumi, Fukuoka-ken (JP)

Correspondence Address: AMIN, TUROCY & CALVIN, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/240,344

(22) Filed: Sep. 29, 2008

(30) Foreign Application Priority Data
Sep. 28, 2007 (JP) 2007-253311
Oct. 18, 2007 (JP) 2007-271208

(51) Int. Cl. H01L 29/78; H01L 21/762

(52) U.S. Cl. 257/396; 438/424; 257/E29.255; 257/E21.545

(57) ABSTRACT

A semiconductor device includes a semiconductor substrate including a plurality of device regions and a device isolation region defining the device regions, and a semiconductor element located in a major surface of the semiconductor substrate and formed in at least one of the device regions. The device isolation region has a DTI (deep trench isolation) structure and has a bottom exposed to a backside of the semiconductor substrate.

### CROSS-REFERENCE TO RELATED APPLICATIONS

This application is based upon and claims the benefit of priority from the prior Japanese Patent Applications No. 2007-253311, filed on Sep. 28, 2007 and No. 2007-271208, filed on Oct. 18, 2007; the entire contents of which are incorporated herein by reference.

### BACKGROUND OF THE INVENTION

1. Field of the Invention

This invention relates to a semiconductor device and a method for manufacturing the same.

2. Background Art

It is conventionally known that a transistor, such as a CMOS transistor, formed on an SOI (silicon on insulator) substrate has a small junction capacitance between the source/drain and the silicon substrate, and hence can operate faster than a transistor formed on a bulk silicon substrate (see JP-A 2006-287006 (Kokai). The SOI substrate is composed of a bulk silicon substrate and a silicon single crystal film formed thereon through the intermediary of an insulating film such as a silicon oxide film.

The SOI substrate is formed by a method of laminating a silicon substrate through the intermediary of an oxide film, or a method of introducing a silicon oxide film into the silicon substrate illustratively by ion implantation However, the SOI substrate thus formed is more complex and expensive than silicon substrates formed by the conventional manufacturing process.

JP-A 2004-273604 (Kokai) discloses a method for manufacturing a semiconductor device by which a thin-film semiconductor device can be manufactured with high yield. More specifically, this method includes the step of forming, on a surface of a semiconductor wafer provided with soldering bumps above a semiconductor substrate, a resin layer filling the gap between the soldering bumps and exhibiting a first adhesive force to the semiconductor wafer, the step of laminating on the resin layer a back grinding tape exhibiting a second adhesive force larger than the first adhesive force to the resin layer, the step of grinding the backside of the semiconductor substrate, and the step of peeling the back grinding tape from the semiconductor wafer, in which step the resin layer is peeled together with the back grinding tape.

Recent semiconductor devices include a device isolation region having a trench structure such as STI (shallow trench isolation) and DTI (deep trench isolation) (see JP-A 2004-047527 (Kokai)). In STI, a shallow trench is formed in the device isolation region and filled with an insulating film such as a silicon oxide film. In DTI, a deep trench is formed in the device isolation region and filled with an insulating film such as a silicon oxide film. Furthermore, a semiconductor device having a WCSP (wafer chip scale package) package is known as a thin package. In this device, semiconductor elements such as bipolar transistors and MOS transistors are formed in a surface region of the semiconductor substrate major surface, which is covered with a protective insulating film. The surface of the protective insulating film is further sealed with a mold resin such as epoxy resin.

In the recent market trend of semiconductor devices, there is a strong demand for guarantee of high-temperature operation. Furthermore, conventional packages have limited improvement in heat dissipation characteristics. This also applies to thin semiconductor devices with a WCSP package described above.

### SUMMARY OF THE INVENTION

According to an aspect of the invention, there is provided a semiconductor device including: a semiconductor substrate including a plurality of device regions and a device isolation region defining the device regions; and a semiconductor element located in a major surface of the semiconductor substrate and formed in at least one of the device regions, the device isolation region having a DTI (deep trench isolation) structure and having a bottom exposed to a backside of the semiconductor substrate.

According to another aspect of the invention, there is provided a method for manufacturing a semiconductor device, including: forming a device isolation region having a DTI structure and a plurality of device regions defined by the device isolation region in a major surface of a semiconductor substrate; forming at least one semiconductor element in the plurality of device regions; and after forming the semiconductor element, polishing or etching a backside of the semiconductor substrate so that the bottom of the device isolation region is exposed.

### BRIEF DESCRIPTION OF THE DRAWINGS

FIG. 1A is a cross-sectional view and FIG. 1B is a perspective view of a semiconductor device configured as a CSP (chip scale package) described in the first embodiment;

FIGS. 2A through 2C are a cross-sectional views of a manufacturing process for forming the semiconductor device shown in FIGS. 1A and 1B;

FIG. 3A is a cross-sectional view and FIGS. 3B and 3C are perspective views of a semiconductor device described in the second embodiment:

FIG. 4 is a cross-sectional view of a semiconductor device of the MCP (multichip package) type in which a chip is stacked shown in FIG. 3;

FIG. 5 is a perspective view of a semiconductor device of the BGA (ball grid array) type configured as a CSP (chip scale package) described in the third embodiment with the backside facing up;

FIG. 6 is a cross-sectional view of the semiconductor device shown in FIG. 5;

FIG. 7 is a cross-sectional view of a manufacturing process of the fourth embodiment; and

FIG. 8 is a cross-sectional view of a manufacturing process of the fourth embodiment.

### DETAILED DESCRIPTION OF THE INVENTION

Embodiments of the invention will now be described with reference to examples.

### First Embodiment

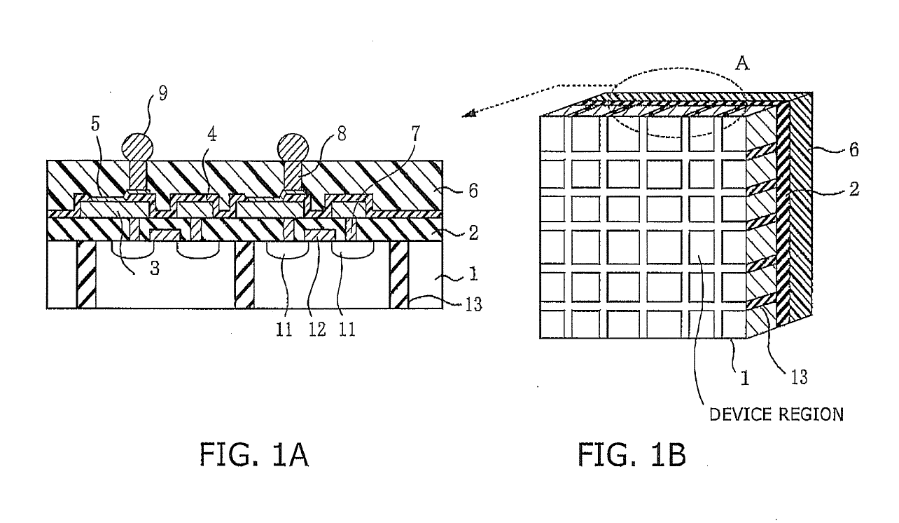

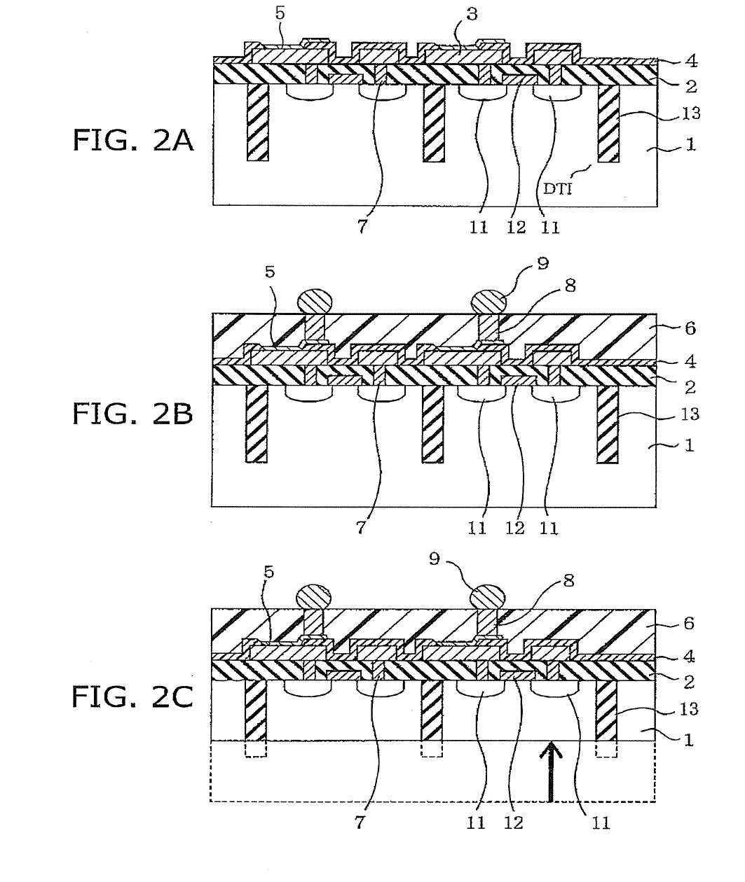

A first embodiment is described with reference to FIGS. 1 and 2.

FIG. 1 shows a cross-sectional view (FIG. 1A) and a perspective view (FIG. 1B) of a semiconductor device configured as a CSP (chip scale package) described in this embodiment, and FIG. 2 is a cross-sectional view of a manufacturing process for forming this semiconductor device. The region A of the upper surface in the perspective view shown in FIG. 1B corresponds to the cross-sectional view of FIG. 1A. As shown in FIG. 1, a semiconductor substrate 1 illustratively made of silicon includes a device isolation region 13 for defining a device region. The device region includes a MOS transistor. The MOS transistor has source/drain regions 11 formed in the surface region of the major surface of the semiconductor substrate 1 and a gate 12 illustratively made of polysilicon formed through the intermediary of a gate insulating film on the portion between the source/drain regions 11. The major surface of the semiconductor substrate 1 is covered with an interlayer insulating film 2 illustratively made of silicon oxide (SiO₂). The interlayer insulating film 2 covers the gate 12 of the MOS transistor. A plurality of aluminum (Al) pads 3 are provided on the surface of the interlayer insulating film 2. The aluminum pad 3 is electrically connected to the source or drain region 11 through the intermediary of a coupling interconnect 7 illustratively made of tungsten buried in the interlayer insulating film 2.

The interlayer insulating film 2 and the aluminum pads 3 formed thereon are covered with a protective insulating film 4 illustratively made of polyimide. Some of the aluminum pads 3 are partly exposed from the protective insulating film 4. A copper (Cu) interconnect 5 is provided on the exposed portion of the aluminum pad 3. The copper interconnect 5 extends from the exposed portion of the aluminum pad 3 to the top of the protective insulating film 4 adjacent to the exposed portion. A mold resin 6 is provided on the major surface of the semiconductor substrate 1 and covers the protective insulating film 4.

A plurality of solder balls 9 serving as the external connection terminals of this semiconductor device are placed on the surface of the mold resin 6. The solder ball 9 is electrically connected to the extending portion of the copper interconnect 5 through the intermediary of a copper (Cu) post 8, which is a coupling interconnect buried in the mold resin 6.

Next, a method for manufacturing the semiconductor device of this embodiment is described with reference to FIG. 2.

A silicon wafer illustratively having a thickness of 629 μm is used as the semiconductor substrate 1. A deep trench (DT) having a thickness exceeding approximately 10 μm is formed in the major surface of the semiconductor substrate 1 and filled with a silicon oxide film to form a device isolation region 13 of the DTI structure. The device isolation region 13 defines a device region. In the device region, a source/drain region 11 is formed in the major surface of the semiconductor substrate 1 illustratively by impurity ion implantation, a gate insulating film illustratively made of a silicon oxide film is formed on the portion between the source/drain regions 11, and a gate 12 illustratively made of polysilicon is formed thereon. Thus, a MOS transistor is formed in the device region.

Next, an interlayer insulating film (SiO₂) 2 is formed on the major surface of the semiconductor substrate 1 illustratively by CVD to cover the gate 12 of the MOS transistor. Subsequently, a contact hole is formed in the interlayer insulating film 2 illustratively by etching so that the source region or drain region 11 is exposed at the bottom of the contact hole, and a coupling interconnect 7 illustratively made of copper is formed in the contact hole illustratively by plating (FIG. 2A). Subsequently, an aluminum pad 3 is formed so as to be connected to the surface of the coupling interconnect 7 exposed from the interlayer insulating film 2. Next, a protective insulating film 4 is formed on the interlayer insulating film 2 and the aluminum pads 3 formed thereon so that some of the aluminum pads 3 are partly exposed. Subsequently, a copper (Cu) interconnect 5 is provided on the exposed portion of the aluminum pad 3.

Next, a mold resin 6 is formed on the protective insulating film 4 and the copper interconnect 5. A contact hole is formed in this mold resin 6 by RIE or other etching so that the extending portion of the copper interconnect 5 is exposed at the bottom of the contact hole. A copper post 8 is buried in the contact hole illustratively by plating. Next, a plurality of solder balls 9 are connected to the exposed surface of the copper post 8 buried in the mold resin 6 (FIG. 2B). Alternatively, this step of connecting the solder balls 9 can be performed after the step shown in FIG. 2C.

Next, the backside of the semiconductor substrate 1 is thinned by polishing such as CMP (chemical mechanical polishing) or etching. In this embodiment, the semiconductor wafer 629 μm thick is thinned to a thickness of approximately 10 μm so that the bottom of the device isolation region 13 is exposed (FIG. 2C).

The above process can be used to obtain a semiconductor device which is free from junction capacitance to the bulk substrate and allows improvement in operating speed and reduction in current consumption. Furthermore, because there is no silicon oxide film as in the SOI substrate, heat dissipation of the semiconductor device is improved. In this manufacturing method, conventional processes for a semiconductor device based on the SOI substrate can be directly used, and its design concept is directly applicable.

### Second Embodiment

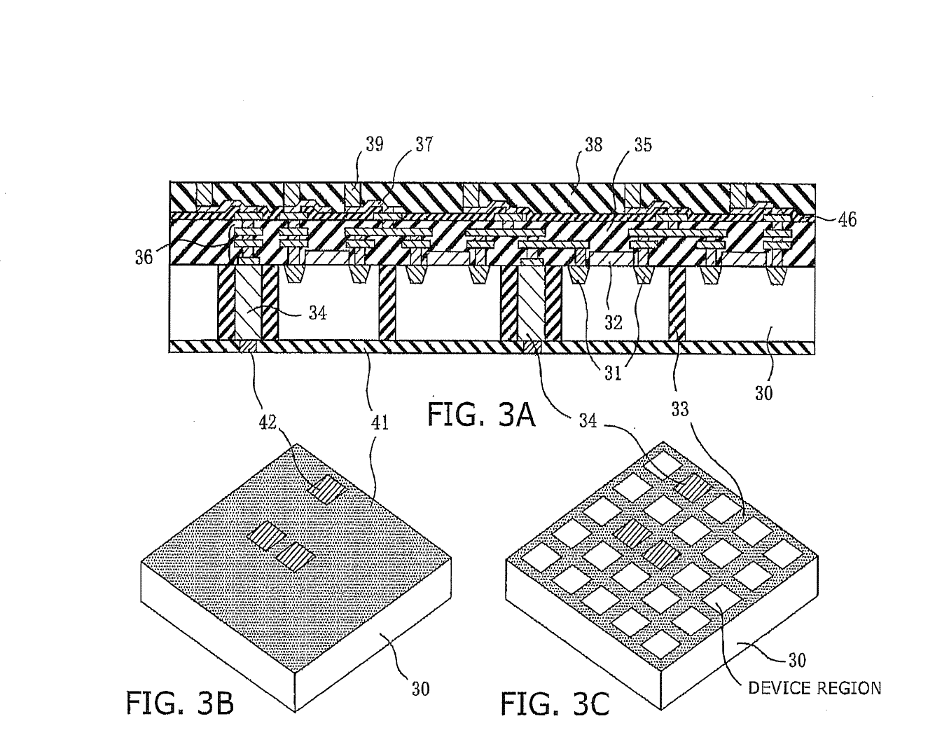

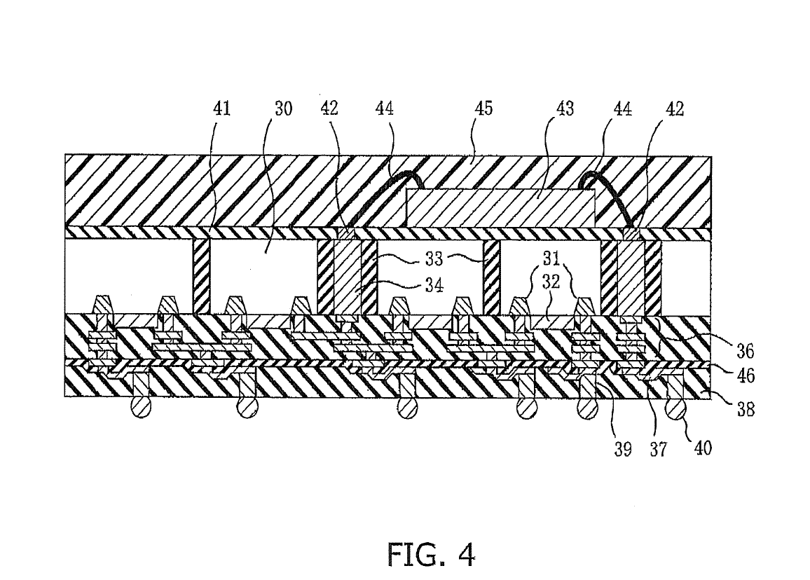

Next, a second embodiment is described with reference to FIGS. 3 and 4.

FIG. 3 shows a cross-sectional view (FIG. 3A) and perspective views (FIGS. 3B and 3C) of a semiconductor device described in this embodiment, and FIG. 4 is a cross-sectional view of a semiconductor device of the MCP (multichip package) type in which a chip is stacked. As shown in FIG. 3, a semiconductor substrate 30 illustratively made of silicon includes a device isolation region 33 for defining a device region. The device region includes a MOS transistor. A current-carrying region 34 highly doped with boron or other impurity is formed in some of the device regions. The MOS transistor has source/drain regions 31 formed in the surface region of the major surface of the semiconductor substrate 30 and a gate 32 illustratively made of polysilicon formed through the intermediary of a gate insulating film on the portion between the source/drain regions 31. The major surface of the semiconductor substrate 30 is covered with an interlayer insulating film 35 illustratively made of silicon oxide (SiO₂). The interlayer insulating film 35 covers the gate 32 of the MOS transistor. The interlayer insulating film 35 is covered with a protective insulating film 46 illustratively made of polyimide.

A plurality of coupling interconnects 37 illustratively made of a metal film is provided on the surface of the protective Insulating film 46. The coupling interconnect 37 is electrically connected to the source or drain region 31 through the intermediary of a coupling interconnect structure 36 buried in the interlayer insulating film 35. Furthermore, the coupling interconnect 37 is also electrically connected to the current-carrying region 34 formed inside the semiconductor substrate 30. The coupling interconnect structure 36 is composed of a first and second aluminum interconnect layer and a connecting post for connecting therebetween.

The coupling interconnects 37 and the protective insulating film 46 are sealed with epoxy or other mold resin 38. A plurality of copper posts 39 serving as coupling interconnects are formed in the mold resin 38. The copper post 39 is connected to the coupling interconnect 37. A silicon oxide film 41 covers the backside of the semiconductor substrate 30 except the portion of the current-carrying region 34, where a connection pad 42 illustratively made of aluminum is formed on the current-carrying region 34 and exposed from the silicon oxide film 41 (FIG. 3).

Next, a solder ball 40 serving as an external connection terminal is connected to the copper post 39 exposed from the mold resin 38. On the other hand, a silicon chip 43 is mounted on the silicon oxide film 41, and the electrodes (not shown) of the silicon chip 43 are electrically connected to the connection pads 42 by bonding wires 44. The silicon chip 43 and the bonding wires 44 are sealed with a mold resin 45 (FIG. 4).

The signal of the silicon chip 43 flows through the connection pad 42 to the current-carrying region 34, passes through the coupling interconnect structure 36, the coupling interconnect 37, and the copper post 39, and is sent outside from the solder ball 40. The source/drain region 31 of the MOS transistor formed in the semiconductor substrate 30 is electrically connected to the solder ball 40 through the intermediary of the coupling interconnect structure 36, the coupling interconnect 37, and the copper post 39.

The silicon chip is electrically connected to the MOS transistor formed in the semiconductor substrate by the bonding wires. Alternatively, solder balls can be used instead of the bonding wires.

The above process can be used to obtain a semiconductor device which is free from junction capacitance to the bulk substrate and allows improvement in operating speed and reduction in current consumption. Furthermore, because there is no silicon oxide film as in the SOI substrate, heat dissipation of the semiconductor device is improved. Because this embodiment uses a current-carrying region formed in the semiconductor substrate, there is no need to draw out bonding wires to the periphery of the chip, allowing a stacked semiconductor device with low cost and small size to be obtained.

### Third Embodiment

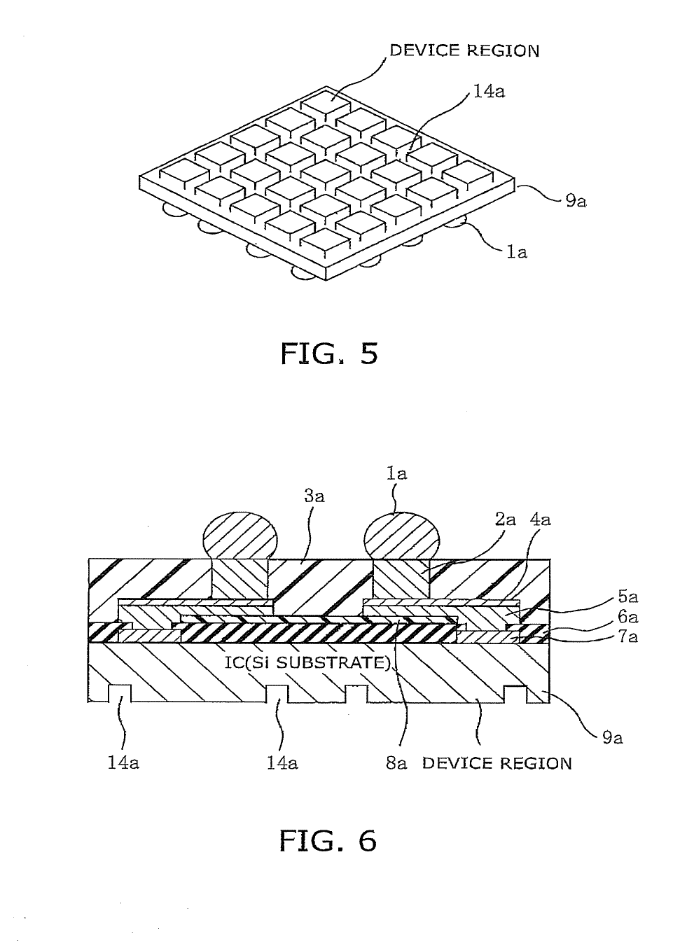

Next, a third embodiment is described with reference to FIGS. 5 and 6.

FIG. 5 is a perspective view of a semiconductor device of the BGA (ball grid array) type configured as a CSP (chip scale package) described in this embodiment with the backside facing up, and FIG. 6 is a cross-sectional view of the semiconductor device shown in FIG. 5. As shown in FIG. 5, a semiconductor substrate 9a illustratively made of silicon includes a device isolation region 14a for defining a device region. In FIG. 6, the semiconductor substrate 9a also includes a multilayer interconnect for electrically connecting an internal semiconductor element to an aluminum pad 7a on the surface, and an interlayer insulating film for holding the multilayer interconnect. The device isolation region 14a has a DTI trench structure, in which the DTI trench bottom is exposed to the backside of the semiconductor substrate 9a, and the inside of the trench is hollowed. The device region includes a semiconductor element (not shown). The semiconductor element formed in the device region can be a bipolar transistor, a MOS transistor, a CMOS transistor, or a BiCMOS transistor, or a passive element can be placed therein. The fourth embodiment described below will be described using a bipolar transistor (NPNTr).

The semiconductor element is formed in the surface region of the major surface of the semiconductor substrate 9a, and its electrode is electrically connected to an aluminum pad 7a, which is a connection electrode formed on the major surface of the semiconductor substrate 9a. The aluminum pad 7a is illustratively made of Al—Si—Cu/Al—Cu.

The major surface of the semiconductor substrate 9a is covered with a protective insulating film 6a illustratively made of SiN. At least part of the protective insulating film 6a is covered with a polyimide insulating film 8a. The surface of the aluminum pad 7a is partly exposed from the protective insulating film 6a. A barrier metal layer (UBM) 5a illustratively made of Ti/Cu is formed on the exposed portion of the aluminum pad 7a. The barrier metal layer 5a joined to the aluminum pad 7a extends on the protective insulating film 6a and the polyimide insulating film 8a. A copper interconnect layer 4a is formed on the barrier metal layer 5a. The copper interconnect layer 4a and the barrier metal layer 5a constitute a coupling interconnect. The major surface of the semiconductor substrate 9a is sealed with epoxy or other mold resin 3a so that the copper interconnect 4a, the barrier metal layer 5a, the protective insulating film 6a, the aluminum pad 7a, and the polyimide Insulating film 8a are covered therewith.

Solder balls 1a are arrayed on the mold resin 3a. The solder ball 1a is attached to the surface of the mold resin 3a, connected to the coupling interconnect 4a, 5a through the intermediary of a copper post 2a serving as a coupling interconnect buried in the mold resin 3a, and electrically connected to the aluminum pad 7a. The aluminum pad 7a is a connection electrode of the semiconductor element formed in the semiconductor substrate 9a and externally supplies the signal inside the semiconductor element. The solder ball 1a is an external terminal of the semiconductor device described in this embodiment and electrically connected to the aluminum pad 7a through the intermediary of the copper post 2a, the copper interconnect layer 4a, and the barrier metal layer 5a.

As described above, the semiconductor device described in this embodiment comprises a semiconductor substrate 9a including a plurality of device regions and a device isolation region 14a defining the device regions, and a semiconductor element formed in the device region. The device isolation region 14a has a DTI structure. The bottom of the device isolation region 14a is exposed to the backside of the semiconductor substrate 9a, and the inside of the device isolation region 14a is hollowed.

The oxide film or other insulating film inside the DTI trench of the device isolation region exposed to the backside of the semiconductor substrate is removed so that the DTI trench is hollowed. Hence, protrusions and depressions are formed on the backside. Thus, wafer warpage at high temperatures is prevented, and chipping and cracking can be avoided. Furthermore, thinning of the semiconductor substrate enables dissipation of self-generated heat from the backside, allowing improvement in heat dissipation characteristics.

### Fourth Embodiment

Next, a fourth embodiment is described with reference to FIGS. 6 to 8.

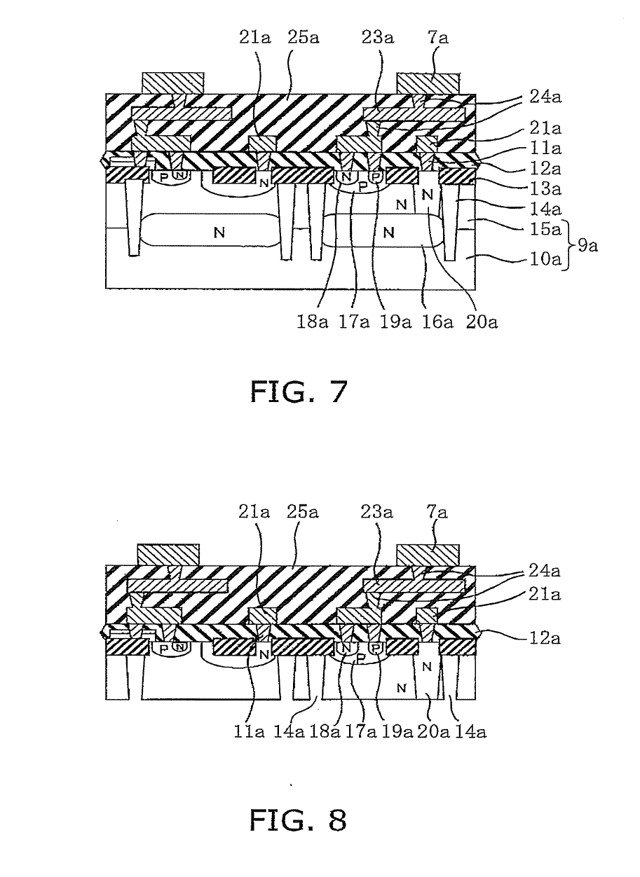

FIGS. 7 and 8 are cross-sectional views of a manufacturing process of this embodiment. In this embodiment, a method for manufacturing the semiconductor device described in the third embodiment is described.

A silicon wafer illustratively having a thickness of 629 μm is used as the semiconductor substrate 9a. The semiconductor substrate 9a is composed of a silicon single crystal substrate 10a and an N-type silicon epitaxial growth layer 15a grown thereon.

The semiconductor substrate 9a includes a highly doped N⁺-buried layer 16a doped at a level between the silicon single crystal substrate 10a and the silicon epitaxial growth layer 15a. First, a trench 13a of the STX (shallow trench isolation) structure filled with a silicon oxide film is formed in the major surface of the semiconductor substrate 9a. Furthermore, a deep trench (DT) having a thickness exceeding approximately 10 μm is formed and filled with a silicon oxide film to form a device isolation region 14a of the DTI structure. The deep trench is not completely filled with the silicon oxide film so that a void occurs in part. The device isolation region 14a is formed from the silicon epitaxial growth layer 15a to the inside of the silicon single crystal substrate 10a. The device isolation region 14a defines a device region. In one of the device regions, an impurity is diffused in the major surface of the N-type silicon epitaxial growth layer 15a illustratively by ion implantation to provide an impurity diffusion region, thereby forming a bipolar transistor (NPNTr).

First, a P-type impurity such as boron is ion implanted to form a P-type base region 17a. Next, an N-type Impurity such as phosphorus or arsenic is ion implanted into the base region 17a to form a highly doped N⁺-emitter region 18a. A highly doped base contact region 19a is formed in the base region 17a. Furthermore, a highly doped collector contact region 20a connected to the N⁺-buried layer 16a is formed.

Next, an interlayer insulating film (SiO₂) 12a is formed on the silicon epitaxial growth layer 15a illustratively by CVD to cover the transistor (NPNTr). Subsequently, a contact hole is formed in the interlayer insulating film 12a illustratively by etching so that the emitter region 18a, the base contact region 19a, and the collector contact region 20a are exposed at the bottom of the contact hole, and a coupling interconnect 11a illustratively made of copper is formed in the contact hole illustratively by plating. Subsequently, an aluminum interconnect (first layer) 21a is formed so as to be connected to the surface of the coupling interconnect 11a exposed from the interlayer insulating film 12a.

In FIG. 7, the first-layer aluminum interconnect 21a is shown. However, a second-layer aluminum interconnect 23a can be also formed. In practice, a third-layer or more aluminum interconnects are formed through the intermediary of an interlayer insulating film 25a, and the aluminum pad 7a shown in FIGS. 6 and 7 is formed on the interlayer insulating film 25a located on the top-layer aluminum interconnect. Connection is provided by coupling interconnects (vias) 24a between the first-layer aluminum interconnect 21a and the second-layer aluminum interconnect 23a, and between the second-layer aluminum interconnect 23a and the aluminum pad 7a, respectively. The mold resin 3a and the solder ball 1a shown in FIG. 6 are formed on the aluminum pad 7a, but are not shown in FIG. 7.

Next, as shown in FIG. 6, a protective insulating film (SiN) 6a is formed on the aluminum pad 7a so that the aluminum pad 7a is partly exposed. Next, a polyimide insulating film 8a is formed on the protective insulating film 6a. Next, a barrier metal layer 5a having a portion extending on the polyimide insulating film 8a is formed on the exposed portion of the aluminum pad 7a. Furthermore, a copper interconnect 4a is formed on the barrier metal layer 5a to serve as a coupling interconnect. Next, a mold resin 3a is formed on the copper interconnect 4a, the barrier metal layer Sa, the protective insulating film 6a, the aluminum pad 7a, and the polyimide insulating film 8a to seal the surface.

A contact hole is formed in the mold resin 3a so that the copper interconnect 4a is exposed at the bottom of the contact hole. The contact hole is filled with copper illustratively by plating to form a copper post 2a serving as a coupling interconnect. The copper post 2a is connected to the copper interconnect 4a, and the upper surface of the copper post 2a exposed to the surface of the mold resin 3a is connected to a solder ball 1a serving as an external terminal.

Next, before or after the step of connecting the solder ball 1a to the copper post 2a, the backside of the semiconductor substrate 9a is thinned to approximately 10 μm illustratively by polishing or etching, such as by CMP (chemical mechanical polishing). Consequently, the device isolation region 14a is exposed to the backside of the semiconductor substrate 9a. Because the inside of the device isolation region 14a is filled with a sparse silicon oxide film including a void, its inside is hollowed after thinning (see FIG. 5). Any remaining oxide film can be removed illustratively by etching as needed. Alternatively, it is also possible to form the device isolation region with its inside filled with a dense silicon oxide film and remove the internal silicon oxide film illustratively by etching after thinning the semiconductor substrate.

As shown in FIG. 8, the backside of the Si semiconductor substrate with the device isolation formed by a hollow trench is ground more deeply than conventional. Then, as shown in FIG. 5, the hollowed device isolation region is turned into a groove, realizing a structure in which a plurality of device regions are arrayed.

In this embodiment, the oxide film or other insulating film inside the DTI trench of the device isolation region exposed to the backside of the semiconductor substrate is removed so that the DTI trench is hollowed. Hence, protrusions and depressions are formed on the backside. Thus, wafer warpage at high temperatures is prevented, and chipping and cracking can be avoided. Furthermore, thinning of the semiconductor substrate enables dissipation of self-generated heat from the backside, allowing improvement in heat dissipation characteristics. Moreover, existing manufacturing techniques are directly used until the step of thinning the semiconductor substrate, and hence the manufacturing process is easily implemented.

The embodiments of the invention have been described with reference to examples. However, the invention is not limited to these examples. More specifically, these examples can be suitably modified by those skilled in the art, and such modifications are also encompassed within the scope of the invention as long as they fall within the spirit of the Invention. For example, each element included in the above examples and its layout, material, condition, shape, size and the like are not limited to those illustrated, but can be suitably modified.

Furthermore, the elements included in the above embodiments can be combined as long as technically feasible, and such combinations are also encompassed within the scope of the invention as long as they fall within the spirit of the Invention.

1. A semiconductor device comprising:
a semiconductor substrate including a plurality of device regions and a device isolation region defining the device regions; and
a semiconductor element located in a major surface of the semiconductor substrate and formed in at least one of the device regions,
the device isolation region having a DTI (deep trench isolation) structure and having a bottom exposed to a backside of the semiconductor substrate.

2. The semiconductor device according to claim 1, wherein a silicon oxide film is buried in the device isolation region.

3. The semiconductor device according to claim 1, wherein the device isolation region is hollowed inside.

4. The semiconductor device according to claim 1, wherein the semiconductor element is a MOS transistor.

5. The semiconductor device according to claim 3, wherein the semiconductor element is a MOS transistor.

6. The semiconductor device according to claim 1, wherein at least any of a mold resin and a protective insulating film are formed on the major surface of the semiconductor substrate so as to cover the semiconductor element.

7. The semiconductor device according to claim 3, wherein at least any of a mold resin and a protective insulating film are formed on the major surface of the semiconductor substrate so as to cover the semiconductor element.

8. The semiconductor device according to claim 1, wherein
an interlayer insulating film is provided on the major surface of the semiconductor substrate, and
a coupling interconnect electrically connected to the semiconductor element is buried in the interlayer insulating film.

9. The semiconductor device according to claim 3, wherein
an interlayer insulating film is provided on the major surface of the semiconductor substrate, and
a coupling interconnect electrically connected to the semiconductor element is buried in the interlayer insulating film.

10. The semiconductor device according to claim 1, wherein an aluminum pad electrically connected to the semiconductor element is provided on the major surface of the semiconductor substrate.

11. The semiconductor device according to claim 3, wherein an aluminum pad electrically connected to the semiconductor element is provided on the major surface of the semiconductor substrate.

12. The semiconductor device according to claim 1, wherein
a current-carrying region extending from the major surface to the backside of the semiconductor substrate is formed in at least one of the device regions,
at least another semiconductor substrate is mounted on the backside of the semiconductor substrate, and
a semiconductor element formed in the other semiconductor substrate is electrically connected to the semiconductor element formed in the semiconductor substrate through the current-carrying region.

13. The semiconductor device according to claim 3, wherein
a current-carrying region extending from the major surface to the backside of the semiconductor substrate is formed in at least one of the device regions,
at least another semiconductor substrate is mounted on the backside of the semiconductor substrate, and
a semiconductor element formed in the other semiconductor substrate is electrically connected to the semiconductor element formed in the semiconductor substrate through the current-carrying region.

14. A method for manufacturing a semiconductor device, comprising:
forming a device isolation region having a DTI structure and a plurality of device regions defined by the device isolation region in a major surface of a semiconductor substrate;
forming at least one semiconductor element in the plurality of device regions; and
after forming the semiconductor element, polishing or etching a backside of the semiconductor substrate so that the bottom of the device isolation region is exposed.

15. The method for manufacturing a semiconductor device according to claim 14, further comprising, after said etching:
hollowing the inside of the device isolation region.

16. The method for manufacturing a semiconductor device according to claim 15, wherein said forming a device isolation region includes forming a dense silicon oxide film in a region where the device isolation region is to be formed.

17. The method for manufacturing a semiconductor device according to claim 15, wherein said forming a device isolation region includes forming a silicon oxide film in a region where the device isolation region is to be formed so that a void occurs in part.

18. The method for manufacturing a semiconductor device according to claim 1S, wherein said hollowing the inside of the device isolation region includes removing a material Inside the device isolation region by etching.

19. The method for manufacturing a semiconductor device according to claim 14, further comprising,
after forming the semiconductor element and before polishing or etching the backside of the semiconductor substrate, covering the major surface of the semiconductor substrate with a mold resin and a protective insulating film.

20. The method for manufacturing a semiconductor device according to claim 14, further comprising:
forming a current-carrying region in at least one of the device regions;
forming a silicon oxide film on a portion of the backside of the semiconductor substrate other than the current-carrying region and forming a conductive connection pad on the current-carrying region; and
forming a silicon chip on the backside of the semiconductor substrate so that the silicon chip is electrically connected to the connection pad.
